(19) United States
(12) Patent Application Publication
(10) Pub. No.: US 2025/0386745 A1
(43) Pub. Date: Dec. 18, 2025

(54) RESISTIVE RANDOM ACCESS MEMORY DEVICE INCLUDING A VARIABLE RESISTIVE MEMORY LAYER

(71) Applicant: SAMSUNG ELECTRONICS CO., LTD., SUWON-SI (KR)

(72) Inventors: Minsup KIM, Suwon-si (KR); Sunho KWON, Suwon-si (KR); Sohee KIM, Suwon-si (KR); Yonghwan KIM, Suwon-si (KR); Hyunseob KIM, Suwon-si (KR); Seongsu EOM, Suwon-si (KR); Youngchan LEE, Suwon-si (KR); Jaechang LEE, Suwon-si (KR)

(21) Appl. No.: 19/013,111

(22) Filed: Jan. 8, 2025

(30) Foreign Application Priority Data
Jun. 18, 2024 (KR) 10-2024-0079098

(51) Int. Cl. H10N 70/00; H10B 63/00

(52) U.S. Cl. CPC H10N 70/841; H10B 63/30; H10N 70/8833; H10N 70/8836; H10B 63/80; H10N 70/023; H10N 70/063

(57) ABSTRACT

A resistive memory device includes: a substrate; a switching component disposed on the substrate; a first interlayer insulation layer disposed on the substrate and covering the switching component; a contact disposed in a contact hole, which passes through the first interlayer insulation layer, and electrically connected to the switching component; a resistive memory unit disposed on the first interlayer insulation layer and electrically connected to the contact, wherein the resistive memory unit includes a lower electrode, a variable resistive material pattern, and an upper electrode sequentially disposed on the first interlayer insulation layer; and a first wiring line disposed on the resistive memory unit and extending in a first horizontal direction that is parallel to an upper surface of the substrate, wherein the first wiring line includes aluminum.

### CROSS-REFERENCE TO RELATED APPLICATION

This application claims priority under 35 U.S.C. § 119 to Korean Patent Application No. 10-2024-0079098, filed on Jun. 18, 2024, in the Korean Intellectual Property Office, the disclosure of which is incorporated by reference herein in its entirety.

### TECHNICAL FIELD

The present inventive concept relates to a resistive memory device, and more particularly, to a resistive random access memory device including a variable resistive memory layer.

### DISCUSSION OF THE RELATED ART

As electronic products become lighter, thinner, and more miniaturized, the demand for higher integration in electronic products also increases. Resistive memory devices have been proposed as devices which enable an in-memory computing operation or a neuromorphic computing operation to be efficiently and rapidly performed. Generally, resistive memory devices include a variable resistive dielectric material layer that is disposed between two electrodes, and a resistive memory device may be disposed between metal wirings of a back-end-of-line (BEOL).

### SUMMARY

According to embodiments of the present inventive concept, a resistive memory device includes: a substrate; a switching component disposed on the substrate; a first interlayer insulation layer disposed on the substrate and covering the switching component; a contact disposed in a contact hole, which passes through the first interlayer insulation layer, and electrically connected to the switching component; a resistive memory unit disposed on the first interlayer insulation layer and electrically connected to the contact, wherein the resistive memory unit includes a lower electrode, a variable resistive material pattern, and an upper electrode sequentially disposed on the first interlayer insulation layer; and a first wiring line disposed on the resistive memory unit and extending in a first horizontal direction that is parallel to an upper surface of the substrate, wherein the first wiring line includes aluminum.

According to embodiments of the present inventive concept, a resistive memory device includes: a first interlayer insulation layer disposed on a substrate; a resistive memory cell disposed on the first interlayer insulation layer; and a back-end-of-line (BEOL) structure covering the resistive memory cell on the first interlayer insulation layer and including a plurality of wiring lines that are disposed at a plurality of vertical levels, wherein the BEOL structure includes a first wiring line that is disposed at a lowermost portion among the plurality of wiring lines, and a lower surface of the first wiring line disposed on an upper surface of the resistive memory cell.

According to embodiments of the present inventive concept, a resistive memory device includes: a substrate; a transistor disposed on the substrate; a first interlayer insulation layer disposed on the substrate and covering the transistor; a contact disposed in a contact hole, which passes through the first interlayer insulation layer, and electrically connected to the transistor; a resistive memory unit disposed on the first interlayer insulation layer and electrically connected to the contact; a lower electrode disposed on the contact; an upper electrode disposed on the lower electrode; a variable resistive material pattern disposed between the lower electrode and the upper electrode; a spacer disposed on a sidewall of the resistive memory unit; a first wiring line disposed on the first interlayer insulation layer and extending in a first horizontal direction parallel to an upper surface of the substrate, wherein the first wiring line includes aluminum; and a second interlayer insulation layer disposed on the first interlayer insulation layer and covering the resistive memory unit and the first wiring line.

### BRIEF DESCRIPTION OF THE DRAWINGS

The above and other aspects of the present inventive concept will become more apparent by describing in detail embodiments thereof, with reference to the accompanying drawings, in which:

FIG. 1 is a circuit diagram illustrating a resistive memory device according to embodiments of the present inventive concept;

FIG. 2 is a layout diagram illustrating a resistive memory device according to embodiments of the present inventive concept;

FIG. 3 is a cross-sectional view taken along line A-A′ of FIG. 2;

FIG. 4 is a cross-sectional view taken along line B-B′ of FIG. 2;

FIG. 5 is an enlarged view of a region CX of FIG. 3;

FIGS. 6 and 7 are cross-sectional views illustrating a resistive memory device according to embodiments of the present inventive concept;

FIG. 8 is an enlarged view of a region CX of FIG. 6;

FIG. 9 is a cross-sectional view illustrating a resistive memory device according to embodiments of the present inventive concept;

FIG. 10 is an enlarged view of a region CX of FIG. 9;

FIG. 11 is a cross-sectional view illustrating a resistive memory device according to embodiments of the present inventive concept;

FIG. 12 is an enlarged view of a region CX of FIG. 11;

FIG. 13 is a cross-sectional view illustrating a resistive memory device according to embodiments of the present inventive concept;

FIG. 14 is an enlarged view of a region CX of FIG. 13; and

FIGS. 15A, 15B, 16A, 16B, 17A, 17B, 18A, 18B, 19A, 19B, 20A, 20B, 21A, 21B, 22A, 22B, 23A, 23B, 24A, and 24B are cross-sectional views illustrating a method of manufacturing a resistive memory device, according to embodiments of the present inventive concept.

### DETAILED DESCRIPTION OF THE EMBODIMENTS

Hereinafter, embodiments of the present inventive concept will be described in detail with reference to the accompanying drawings. In the drawing, like reference characters denote like elements throughout the specification and drawings, and redundant descriptions thereof will be omitted.

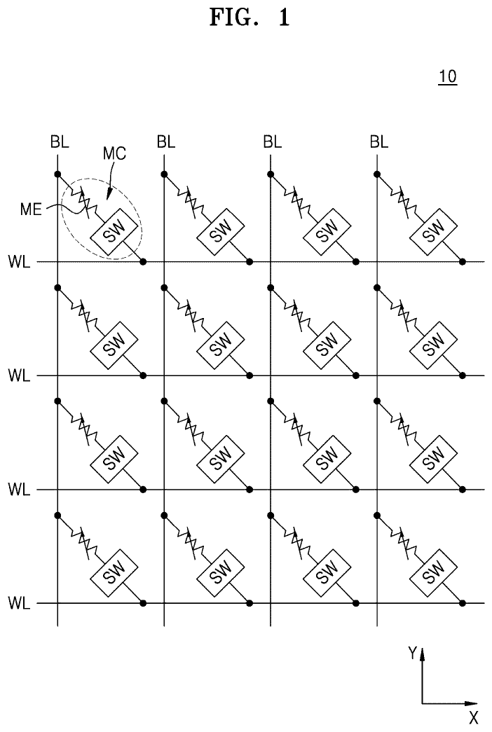

FIG. 1 is a circuit diagram illustrating a resistive memory device 10 according to embodiments of the present inventive concept.

Referring to FIG. 1, the resistive memory device 10 may include a plurality of word lines WL extending in a first horizontal direction X, a plurality of bit lines BL extending in a second horizontal direction Y, and a plurality of memory cells MC connected to the plurality of word lines WL and the plurality of bit lines BL between the plurality of word lines WL and the plurality of bit lines BL.

Each of the plurality of memory cells MC may include a variable resistive memory unit ME for storing information and a switching unit SW for selecting a memory cell MC. In embodiments of the present inventive concept, the switching unit SW may include an access element such as an ovonic threshold switching (OTS) element, a transistor, or a diode. For example, as the switching unit SW of a memory cell MC that is selected through the plurality of word lines WL and the plurality of bit lines BL is turned on, a voltage may be applied to the variable resistive memory unit ME of the memory cell MC, and thus, a current may flow in the variable resistive memory unit ME. For example, the variable resistive memory unit ME may include an insulator or a dielectric material where a resistance varies based on a voltage value applied thereto. For example, a resistance of the variable resistive memory unit ME may be reversibly shifted between a first state and a second state, based on a voltage that is applied to the variable resistive memory unit ME of the selected memory cell MC.

Based on a resistance variation of the variable resistive memory unit ME, digital information such as “0” or “1” may be stored in the memory cell MC, and the digital information may be erased from the memory cell MC. For example, data may be written in a high resistance state “O” and a low resistance state “1” in the memory cell MC. However, the memory cell MC according to embodiments of the present inventive concept is not limited to only the digital information having the high resistance state “0” and the low resistance state “1” and may store various resistance states.

An arbitrary memory cell MC may be addressed by selections of a word line WL and a bit line BL, and as a certain signal is applied between the word line WL and the bit line BL, the memory cell MC may be programmed, and a current value may be measured through the bit line BL, whereby information based on a resistance value of a variable resistive memory unit ME configuring a corresponding memory cell MC may be read out.

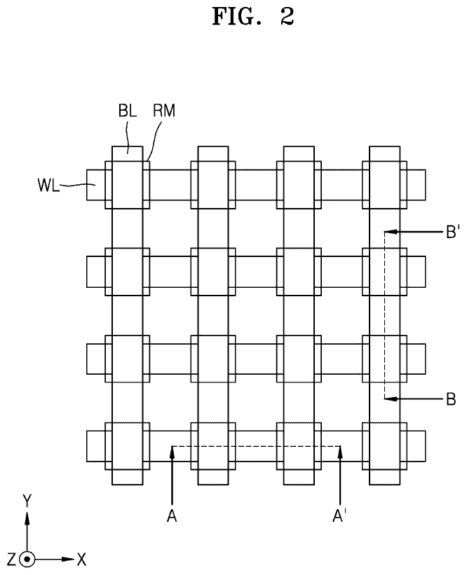

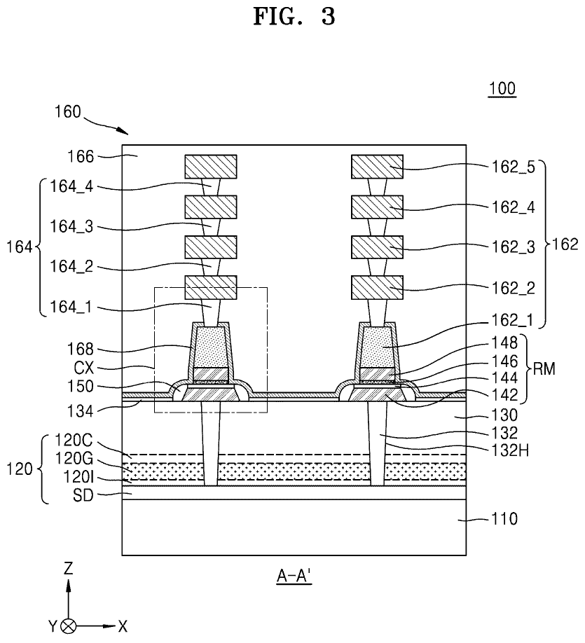

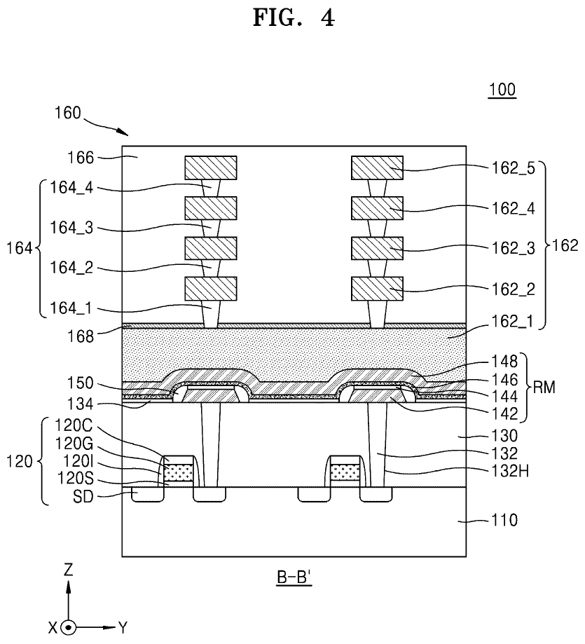

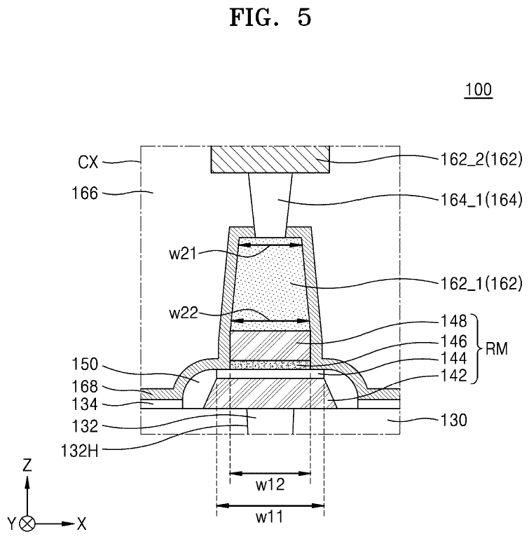

FIG. 2 is a layout diagram illustrating a resistive memory device 100 according to embodiments of the present inventive concept. FIG. 3 is a cross-sectional view taken along line A-A′ of FIG. 2, and FIG. 4 is a cross-sectional view taken along line B-B′ of FIG. 2. FIG. 5 is an enlarged view of a region CX of FIG. 3.

Referring to FIGS. 2 to 5, a transistor 120 and a resistive memory cell RM may be disposed on a substrate 110. A back-end-of-line (BEOL) structure 160 covering the resistive memory cell RM may be disposed on the substrate 110.

In embodiments of the present inventive concept, the transistor 120 may include various kinds of transistors such as a flat transistor, a fin field-effect (FinFET) transistor, a multi bridge channel transistor, a gate all around (GAA)-type transistor, a ferroelectric transistor, and a negative charge transistor. The transistor 120 may correspond to the switch unit SW (see FIG. 1) described above with reference to FIG. 1.

In FIG. 4, a case where the transistor 120 is a flat transistor is illustrated, and for example, the transistor 120 may include a gate insulation layer 120I, a gate electrode 120G, and a gate capping layer 120C, which are sequentially disposed on an upper surface of the substrate 110. In addition, the transistor 120 may include a gate spacer 120S, which is disposed on sidewalls of the gate insulation layer 120I, the gate electrode 120G, and the gate capping layer 120C, and a source/drain region SD disposed in the substrate 110 at sides (e.g., opposing sides) of the gate spacer 120S.

In embodiments of the present inventive concept, instead of the transistor 120, a switching element such as a diode, an OTS element, or a unipolar switching element may be disposed on the substrate 110.

A first interlayer insulation layer 130 covering the transistor 120 may be disposed on the substrate 110. For example, the first interlayer insulation layer 130 may be formed to have a sufficiently large thickness which fully covers an upper surface of the transistor 120. In embodiments of the present inventive concept, the first interlayer insulation layer 130 may include silicon oxide or silicon oxycarbonitride (SiOCN).

A contact 132 may be disposed in a contact hole 132H that passes through the first interlayer insulation layer 130. The contact 132 may be electrically connected to the source/drain region SD of the transistor 120. For example, the contact 132 may include a metal material (for example, tungsten (W)) that completely fills the contact hole 132H.

An etch stop layer 134 may be disposed on the first interlayer insulation layer 130; however, the present inventive concept is not limited thereto. The etch stop layer 134 may be disposed to have a relatively thin thickness on an upper surface of the first interlayer insulation layer 130.

The resistive memory cell RM (or a resistive memory unit) may be disposed on the first interlayer insulation layer 130. The resistive memory cell RM may include a lower electrode 142, a variable resistive material pattern 144, a middle conductive pattern 146, and an upper electrode 148. A spacer 150 may be disposed on at least a portion of a sidewall of the resistive memory cell RM. The resistive memory cell RM may correspond to the variable resistive memory unit ME (see FIG. 1) described above with reference to FIG. 1.

In embodiments of the present inventive concept, the lower electrode 142 may be disposed on an upper surface of each of the first interlayer insulation layer 130 and the contact 132, and a lower surface of the lower electrode 142 may contact the upper surface of the contact 132 and may be electrically connected to the contact 132. The lower electrode 142 may include a flat profile which extends in a lateral direction on the upper surface of the first interlayer insulation layer 130.

In embodiments of the present inventive concept, as illustrated in FIG. 5, both sidewalls of the lower electrode 142 may be inclined so that a distance between the both sidewalls of the lower electrode 142 increases as the lower surface of the lower electrode 142 is approached from the upper surface of the lower electrode 142, and for example, a width of the upper surface of the lower electrode 142 may be less than that of the lower surface of the lower electrode 142. For example, the lower electrode 142 may have a tapered shape. In embodiments of the present inventive concept, the both sidewalls of the lower electrode 142 may be vertical, and a width of the upper surface of the lower electrode 142 may be equal or similar to that of the lower surface of the lower electrode 142.

In embodiments of the present inventive concept, the lower electrode 142 may include at least one of titanium, titanium nitride, aluminum, platinum, tantalum, and/or tantalum nitride.

In embodiments of the present inventive concept, the variable resistive material pattern 144 may be disposed on the upper surface of the lower electrode 142. The variable resistive material pattern 144 may include a flat profile which extends in a lateral direction on the upper surface of the lower electrode 142.

In embodiments of the present inventive concept, an electrical path such as filament may be formed based on the difference between voltages that are applied to both ends of the variable resistive material pattern 144, and thus, the variable resistive material pattern 144 may include a material where an internal resistance varies. For example, the filament may be formed by an oxygen vacancy based on the movement of oxygen molecules included in the variable resistive material pattern 144.

In embodiments of the present inventive concept, the variable resistive material pattern 144 may include a perovskite-based material or transition metal oxide. The perovskite-based material may include, for example, SrTiO₃, BaTiO₃, or Pr_{1-X}Ca_{X}MnO₃, and the transition metal oxide may include, for example, titanium oxide (TiOₓ), zirconium oxide (ZrOₓ), aluminum oxide (AlOₓ), hafnium oxide (HfOₓ), tantalum oxide (TaOₓ), niobium oxide (NbOₓ), cobalt oxide (CoOₓ), tungsten oxide (WOₓ), lanthanum oxide (LaOₓ), or zinc oxide (ZnOₓ). These materials may be used individually, or a combination of two or more of these materials may be used. In embodiments of the present inventive concept, the variable resistive material pattern 144 may have a single-layered structure including the material described above, or may have a complex layer structure where a plurality of layers are stacked on each other. In embodiments of the present inventive concept, the variable resistive material pattern 144 may have a thickness of about 5 nm to about 20 nm, but the present inventive concept is not limited thereto.

The spacer 150 may be disposed to at least partially surround a sidewall of the lower electrode 142 and a sidewall of the variable resistive material pattern 144. In embodiments of the present inventive concept, the spacer 150 may include silicon oxide or silicon nitride. As illustrated in FIGS. 3 and 4, the spacer 150 may be disposed to surround the sidewall of the lower electrode 142 and the sidewall of the variable resistive material pattern 144. For example, the spacer 150 may be disposed to surround all of the sidewall of the lower electrode 142 and the sidewall of the variable resistive material pattern 144.

The middle conductive pattern 146 may be disposed between the variable resistive material pattern 144 and the upper electrode 148. In embodiments of the present inventive concept, the middle conductive pattern 146 may include titanium or titanium nitride.

The upper electrode 148 may be disposed on the middle conductive pattern 146. In embodiments of the present inventive concept, the upper electrode 148 may include at least one of titanium, titanium nitride, aluminum, platinum, tantalum, and tantalum nitride.

In embodiments of the present inventive concept, the middle conductive pattern 146 and the upper electrode 148 may have a line shape which extends in the second horizontal direction Y. In embodiments of the present inventive concept, the middle conductive pattern 146 and the upper electrode 148 may extend from an upper surface of the variable resistive material pattern 144 to an upper surface of the spacer 150 and may extend to the upper surface of the first interlayer insulation layer 130 (or an upper surface of the etch stop layer 134). The middle conductive pattern 146 and the upper electrode 148 may extend in the second horizontal direction Y and may vertically overlap a plurality of variable resistive material patterns 144 that are arranged in the second horizontal direction Y.

In embodiments of the present inventive concept, as illustrated in FIG. 5, the variable resistive material pattern 144 may have a first width w11 in the first horizontal direction X, and the middle conductive pattern 146 may have a second width w12 which is less than the first width w11 in the first horizontal direction X. For example, because the middle conductive pattern 146 has the second width w12 which is less than the first width w11 in the first horizontal direction X, upper surfaces of both ends (e.g., opposing ends) of the variable resistive material pattern 144 in the first horizontal direction X might not be covered by middle conductive pattern 146. For example, the middle conductive pattern 146 may only cover a central region of the variable resistive material pattern 144.

In embodiments of the present inventive concept, as illustrated in FIG. 5, the upper electrode 148 may have the second width w12 which is less than the first width w11 of the variable resistive material pattern 144 in the first horizontal direction X. For example, because the upper electrode 148 has the second width w12 which is less than the first width w11 in the first horizontal direction X, upper surfaces of both ends (e.g., opposing ends) of the variable resistive material pattern 144 in the first horizontal direction X might not be covered the upper electrode 148. For example, the upper electrode 148 may only cover a central region of the variable resistive material pattern 144. For example, the middle conductive pattern 146 and the upper electrode 148 may be vertically aligned with each other to expose ends of the variable resistive material pattern 144.

In embodiments of the present inventive concept, the resistive memory device 100 may have a structure (for example, a 1T-1R structure) where one resistor is connected to one transistor. The structure may be a structure where an upper electrode 148 of one resistor (for example, one resistive memory cell RM) is shared with an upper electrode 148 of another register.

The BEOL structure 160 may be disposed on the resistive memory cell RM. The BEOL structure 160 may include a plurality of wiring lines 162 disposed at different vertical levels, a plurality of vias 164 connecting the plurality of wiring lines 162 with each other, and a second interlayer insulation layer 166 covering the plurality of wiring lines 162 and the plurality of vias 164.

In embodiments of the present inventive concept, the plurality of wiring lines 162 may be disposed at a vertical level which is higher than that of the first interlayer insulation layer 130 and may include a first wiring line 162_1, a second wiring line 162_2, a third wiring line 162_3, a fourth wiring line 162_4, and a fifth wiring line 162_5, which are disposed at different vertical levels from each other. The plurality of vias 164 may include a first via 164_1, a second via 164_2, a third via 164_3, and a fourth via 164_4.

In embodiments of the present inventive concept, the first wiring line 162_1 may be a wiring line that is disposed at a lowermost portion of the plurality of wiring lines 162 and may extend in the second horizontal line Y. The first via 164_1 may be disposed on the first wiring line 162_1, and the second wiring line 162_2 may be disposed on the first via 164_1. The second via 164_2 may be disposed on the second wiring line 162_2, and the third wiring line 162_3 may be disposed on the second via 164_2. The third via 164_3 may be disposed on the third wiring line 162_3, and the fourth wiring line 162_4 may be disposed on the third via 164_3. The fourth via 164_4 may be disposed on the fourth wiring line 162_4, and the fifth wiring line 162_5 may be disposed on the fourth via 164_4. In embodiments of the present inventive concept, one wiring line 162 and a via 164 disposed thereunder (for example, the second wiring line 162_2 and the first via 164_1 or the third wiring line 162_3 and the second via 164_2) may be integrally provided, or in other words, provided as one body.

In embodiments of the present inventive concept, the first wiring line 162_1 may be a wiring line that is disposed at the lowermost portion of the plurality of wiring lines 162 and may extend in the second horizontal line Y on the first interlayer insulation layer 130. In embodiments of the present inventive concept, a lower surface of the first wiring line 162_1 may be disposed on the first interlayer insulation layer 130 and an upper surface of the upper electrode 148 of the resistive memory cell RM. For example, the lower surface of the first wiring line 162_1 may directly contact the upper surface of the upper electrode 148.

In embodiments of the present inventive concept, the first wiring line 162_1 may include aluminum or an aluminum alloy. In embodiments of the present inventive concept, the first wiring line 162_1 may be a line pattern which is formed by forming a conductive layer on the first interlayer insulation layer 130 and patterning the conductive layer by using a patterning mask.

In embodiments of the present inventive concept, an upper surface of the first wiring line 162_1 may have a third width w21 in the first horizontal direction X, and the lower surface of the first wiring line 162_1 may have a fourth width w22 which is greater than the third width w21 in the first horizontal direction X. In embodiments of the present inventive concept, as illustrated in FIG. 5, both sidewalls of the first wiring line 162_1 may be inclined so that a distance between both sidewalls of the first wiring line 162_1 increases as the lower surface of the first wiring line 162_1 is approached from the upper surface of the first wiring line 162_1. In embodiments of the present inventive concept, the third width w21 of the upper surface of the first wiring line 162_1 and the fourth width w22 of the lower surface of the first wiring line 162_1 may be equal or similar to each other, and the both sidewalls of the first wiring line 162_1 may be substantially vertical.

In embodiments of the present inventive concept, a sidewall of the first wiring line 162_1 may be aligned with a sidewall of the upper electrode 148 that is disposed under the first wiring line 162_1 and may be aligned with a sidewall of the middle conductive pattern 146 that is disposed under the upper electrode 148. For example, the sidewall of the first wiring line 162_1 and the sidewall of the upper electrode 148 may be connected to each other without a discontinuous portion between the sidewall of the first wiring line 162_1 and the sidewall of the upper electrode 148.

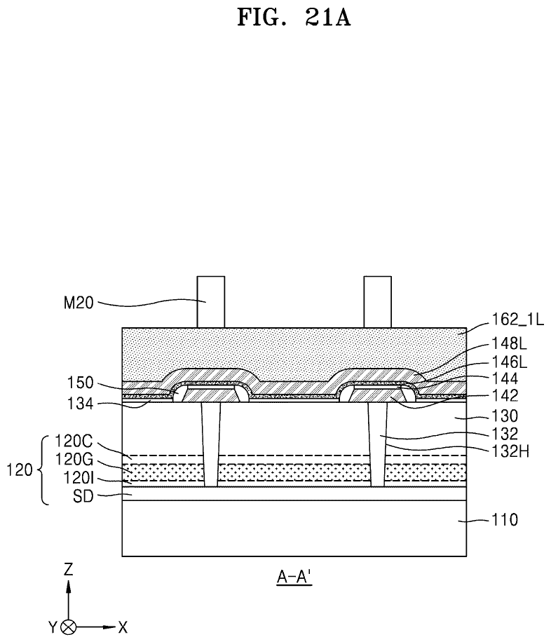

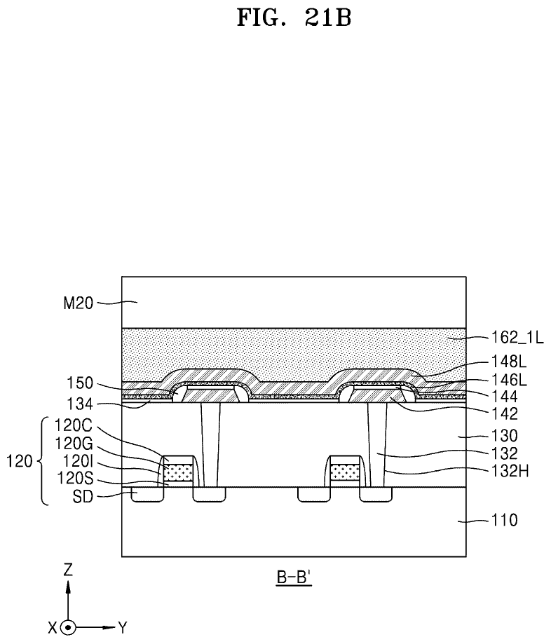

In embodiments of the present inventive concept, the first wiring line 162_1 may be patterned in the same process as or simultaneously with the upper electrode 148 and the middle conductive pattern 146 each disposed under the first wiring line 162_1 or by using the same mask pattern. For example, a mask pattern M20 (see FIG. 21A) may be formed on a conductive layer for forming the first wiring line 162_1, and the first wiring line 162_1, the upper electrode 148, and the middle conductive pattern 146 may be simultaneously or sequentially patterned by using the mask pattern.

The second interlayer insulation layer 166 may cover the plurality of wiring lines 162 and the plurality of vias 164, on the first interlayer insulation layer 130 (or on the etch stop layer 123 optionally). The second interlayer insulation layer 166 may be formed as a stack structure that includes a plurality of insulation layers. The second interlayer insulation layer 166 may include, for example, silicon oxide or SiOC.

A capping liner 168 may be optionally disposed on the upper surface and the sidewall of the first wiring line 162_1. The capping liner 168 may include, for example, silicon nitride or silicon oxide. The capping liner 168 may be a protection layer which may prevent a surface of the first wiring line 162_1 from being damaged in a subsequent process of forming the BEOL structure 160. In embodiments of the present inventive concept, the capping liner 168 may extend from the upper surface and the sidewall of the first wiring line 162_1 to the sidewall of the upper electrode 148 and the sidewall of the middle conductive pattern 146 and may be disposed on an upper surface of at least a portion of the variable resistive material pattern 144 which is not covered by the upper electrode 148.

In embodiments of the present inventive concept, one resistive memory cell RM may be electrically connected to the transistor 120 which is connected to the one resistive memory cell RM through the contact 132. For example, a gate electrode 120G of the transistor 120 may function as a word line WL (see FIG. 1). The first wiring line 162_1 may function as a bit line BL (see FIG. 1) that is connected to the resistive memory cell RM. In a data write operation, the transistor 120 may be turned on by a voltage that is applied to a selected word line WL, a resistance of the resistive memory cell RM electrically connected to the source/drain region SD of the transistor 120 may be changed by a write voltage that is applied to a selected bit line BL (for example, shifted from a high resistance state to a low resistance state, or shifted from the low resistance state to the high resistance state), and data may be stored in the resistive memory cell RM. In addition, in a data read operation, as a current value output from the resistive memory cell RM is sensed based on a read voltage that is applied to the selected bit line BL, data stored in the resistive memory cell RM may be read.

A plurality of peripheral circuit transistors configuring a driving circuit for driving a plurality of memory cells may be formed on the substrate 110. For example, the driving circuit may include peripheral circuits for processing data input/output to/from the plurality of memory cells, and for example, the peripheral circuits may include a pager buffer, a latch circuit, a cache circuit, a column decoder, a sense amplifier, a data in/out circuit, or a row decoder.

Generally, a memory cell including a variable resistive memory layer may be formed in a BEOL structure, and for example, may be disposed between an Mx wiring line and an Mx+1 wiring line. However, a difficulty level of a process of sequentially patterning an upper electrode, the variable resistive memory layer, and a lower electrode may be relatively high. During an etching process of the variable resistive memory layer, a process error where damage such as etch damage occurring on the upper electrode may occur, and due to this, reliability of the memory cell may be reduced.

According to the embodiments described above, first, the lower electrode 142 and the variable resistive material pattern 144 of the variable resistive memory cell RM may be formed on the first interlayer insulation layer 130, and the spacer 150 may be formed on the sidewall of the lower electrode 142 and the variable resistive material pattern 144. Then, after a conductive layer for forming the upper electrode 148 and a conductive layer for forming the first wiring line 162_1 are formed, the upper electrode 148 and the first wiring line 162_1 may be formed by simultaneously patterning the conductive layer for forming the upper electrode 148 and the conductive layer for forming the first wiring line 162_1. According to such a manufacturing method, etch damage may be minimized in a patterning process of the upper electrode 148. Accordingly, the resistive memory cell RM may have increased device performance and/or increased reliability, and the manufacturing cost of the resistive memory device 100 may be reduced.

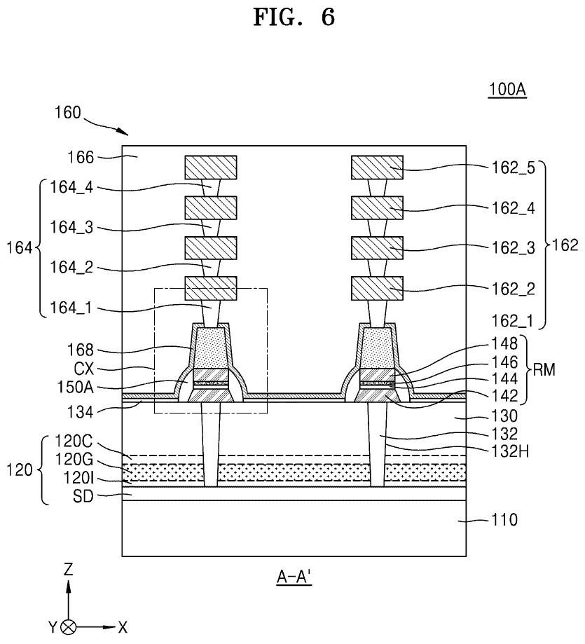

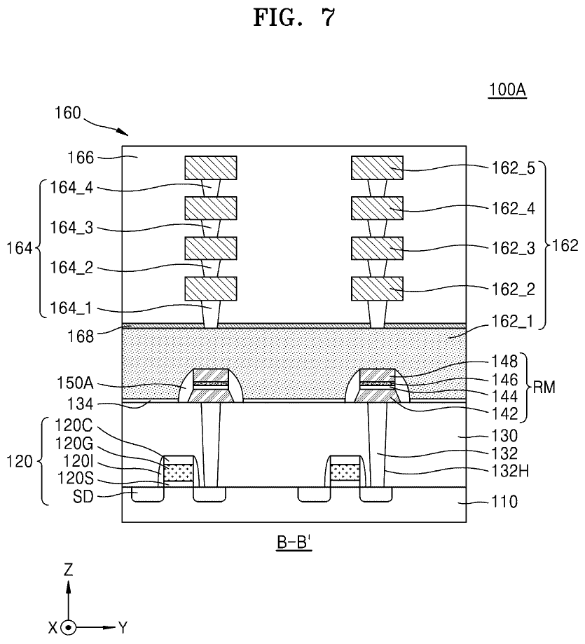

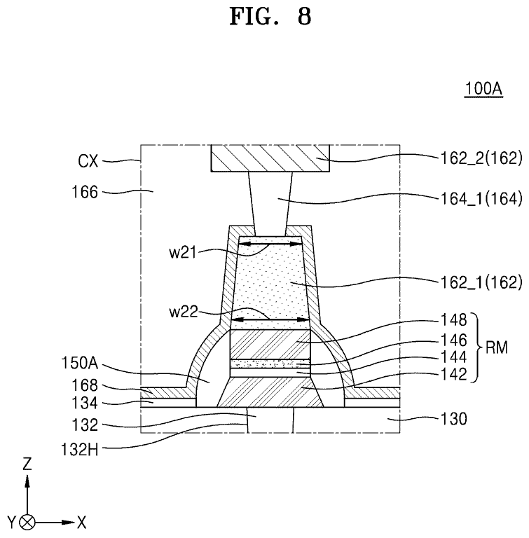

FIGS. 6 and 7 are cross-sectional views illustrating a resistive memory device 100A according to embodiments of the present inventive concept. FIG. 8 is an enlarged view of a region CX of FIG. 6.

Referring to FIGS. 6 to 8, a spacer 150A may be disposed on an entire sidewall of a resistive memory cell RM. A sidewall of a variable resistive material pattern 144, a sidewall of a middle conductive pattern 146, and a sidewall of an upper electrode 148 may be aligned with one another. For example, the sidewall of the lower electrode 142, the sidewall of the variable resistive material pattern 144, the sidewall of the middle conductive pattern 146, and the sidewall of the upper electrode 148 may be continuously connected to one another without forming a discontinuous portion or a stepped portion. For example, the sidewalls of the lower electrode 142 may be slanted with respect to the sidewalls of the variable resistive material pattern 144, the middle conductive pattern 146, and the upper electrode 148. The spacer 150A may be disposed to at least partially surround the sidewall of the lower electrode 142, the sidewall of the variable resistive material pattern 144, the sidewall of the middle conductive pattern 146, and the sidewall of the upper electrode 148. The spacer 150A may be disposed to surround all of the sidewall of the lower electrode 142, the sidewall of the variable resistive material pattern 144, the sidewall of the middle conductive pattern 146, and the sidewall of the upper electrode 148. For example, the spacer 150A may contact a portion of a lower surface of the first wiring line 162_1.

A first wiring line 162_1 may extend in a second horizontal direction Y on the resistive memory cell RM. A lower surface of the first wiring line 162_1 may contact an upper surface of the upper electrode 148. In embodiments of the present inventive concept, the spacer 150A may be disposed between the first wiring line 162_1 and the lower electrode 142 and between the first wiring line 162_1 and the variable resistive material pattern 144.

According to an embodiment of the present inventive concept, because the spacer 150A is formed on the sidewall of the resistive memory cell RM, a sufficient isolation between the first wiring line 162_1 and the lower electrode 142 may be secured.

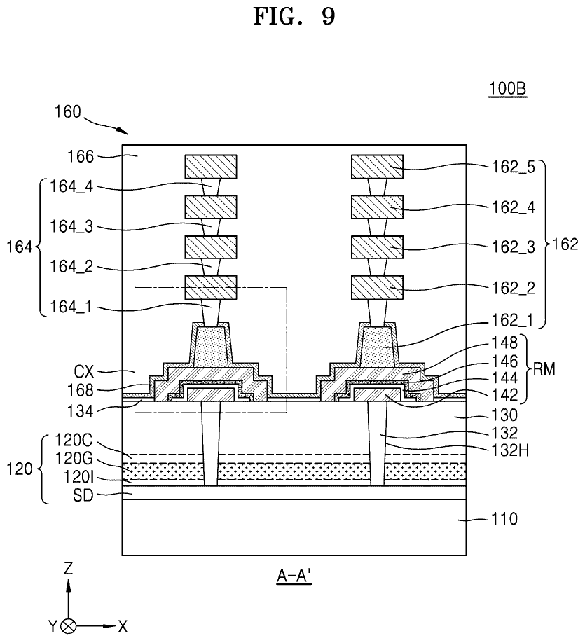

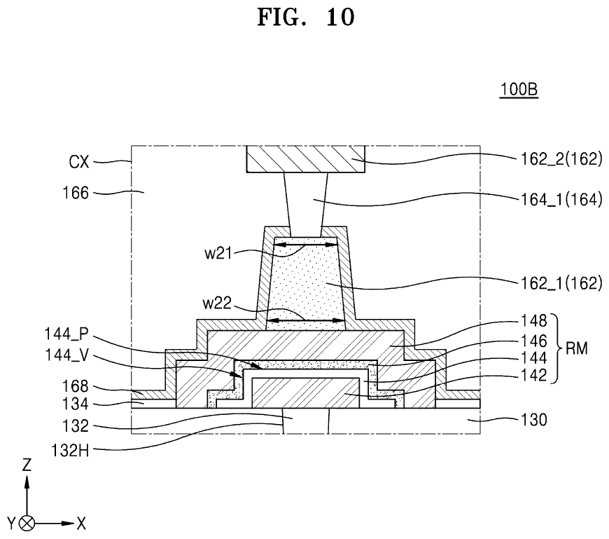

FIG. 9 is a cross-sectional view illustrating a resistive memory device 100B according to embodiments of the present inventive concept. FIG. 10 is an enlarged view of a region CX of FIG. 9.

Referring to FIGS. 9 and 10, a resistive memory cell RM may have a shape including a stepped portion. For example, a lower electrode 142 may be formed to have a rectangular vertical cross-sectional shape, and a variable resistive material pattern 144 may be conformally disposed on an upper surface and a sidewall of the lower electrode 142. Further, an end portion of the variable resistive material pattern 144 may extend to a first interlayer insulation layer 130 (for example, to an etch stop layer 134).

A portion of the variable resistive material pattern 144 that is disposed on an upper surface of the lower electrode 142 may be referred to as a horizontal extension portion 144_P, and a portion of the variable resistive material pattern 144 that is disposed on a sidewall of the lower electrode 142 may be referred to as a vertical extension portion 144_V. The horizontal extension portion 144_P may extend in a lateral direction on the upper surface of the lower electrode 142 and may be disposed to be substantially flat. A stepped portion may be defined at a boundary between an edge portion of the upper surface and a sidewall of the lower electrode 142, and for example, at a boundary between the horizontal extension portion 144_P and the vertical extension portion 144_V of the variable resistive material pattern 144. A middle conductive pattern 146 and an upper electrode 148 may be conformally disposed on the horizontal extension portion 144_P and the vertical extension portion 144_V of the variable resistive material pattern 144.

According to embodiments of the present inventive concept, a boundary between an edge portion of the lower electrode 142 and the horizontal extension portion 144_P and the vertical extension portion 144_V of the variable resistive material pattern 144 adjacent thereto may be a region where an electric field concentrates in a driving operation of the resistive memory device 100B. As an electric field concentrates in a boundary region between the horizontal extension portion 144_P and the vertical extension portion 144_V of the variable resistive material pattern 144, the difference between a resistance value of a low resistance state and a resistance value of a high resistance state may be maximized, and thus, the device performance of the resistive memory device 100B may be increased.

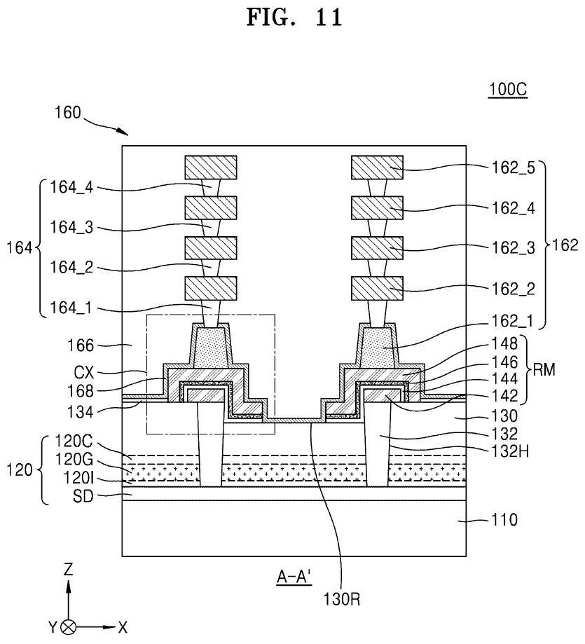

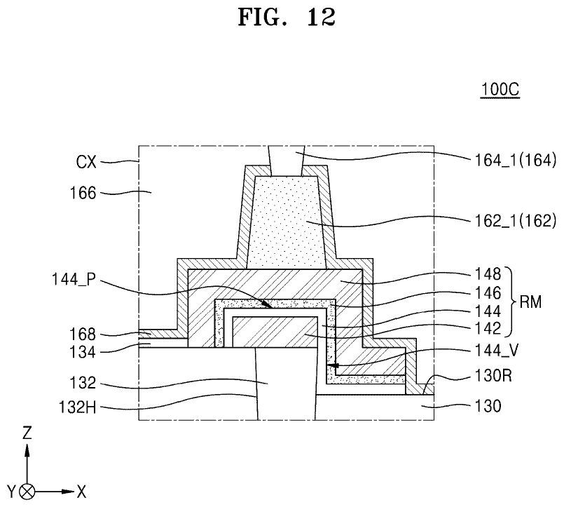

FIG. 11 is a cross-sectional view illustrating a resistive memory device 100C according to embodiments of the present inventive concept. FIG. 12 is an enlarged view of a region CX of FIG. 11.

Referring to FIGS. 11 and 12, a first interlayer insulation layer 130 may include a recess portion 130R, and a sidewall of a lower electrode 142 may be aligned with the recess portion 130R. For example, the sidewall of the lower electrode 142 may be substantially aligned with a sidewall of the recess portion 130R. A variable resistive material pattern 144 may be conformally disposed on an upper surface and a sidewall of the lower electrode 142, and an end portion of the variable resistive material pattern 144 may extend to the recess portion 130R of the first interlayer insulation layer 130. A portion of the variable resistive material pattern 144 disposed on an upper surface of the lower electrode 142 may be referred to as a horizontal extension portion 144_P, and a portion of the variable resistive material pattern 144 which is disposed on a sidewall of the lower electrode 142 and extends to the recess portion 130R may be referred to as a vertical extension portion 144_V. For example, the horizontal extension portion 144_P may be disposed outside the recess portion 130R, and the vertical extension portion 144_V may be disposed in the recess portion 130R. A portion of each of a middle conductive pattern 146 and an upper electrode 148, each which are disposed on the vertical extension portion 144_V, may extend into the recess portion 130R.

The first interlayer insulation layer 130 may include the recess portion 130R, and a stepped portion may be defined at a boundary between an edge portion and a sidewall of the upper surface of the lower electrode 142, and for example, at a boundary between the horizontal extension portion 144_P and the vertical extension portion 144_V of the variable resistive material pattern 144.

According to embodiments of the present inventive concept, a boundary between an edge portion of the lower electrode 142 and the horizontal extension portion 144_P and the vertical extension portion 144_V of the variable resistive material pattern 144 adjacent thereto may be a region where an electric field concentrates in a driving process of the resistive memory device 100C. As an electric field concentrates in a boundary region between the horizontal extension portion 144_P and the vertical extension portion 144_V of the variable resistive material pattern 144, the difference between a resistance value of a low resistance state and a resistance value of a high resistance state may be maximized, and thus, the device performance of the resistive memory device 100C may be increased.

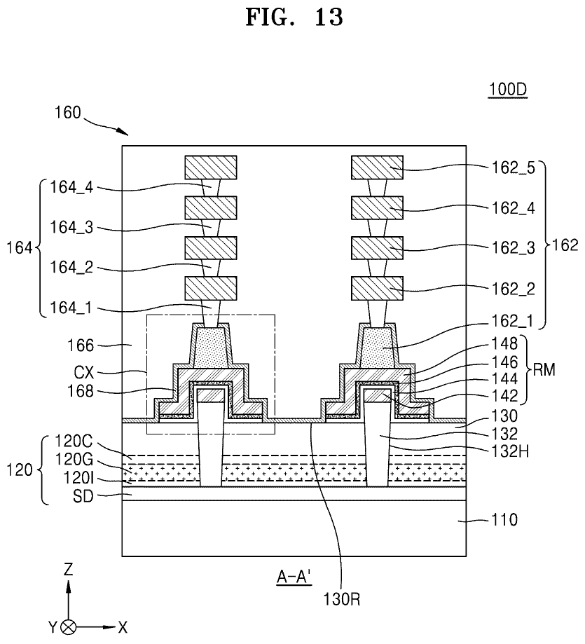

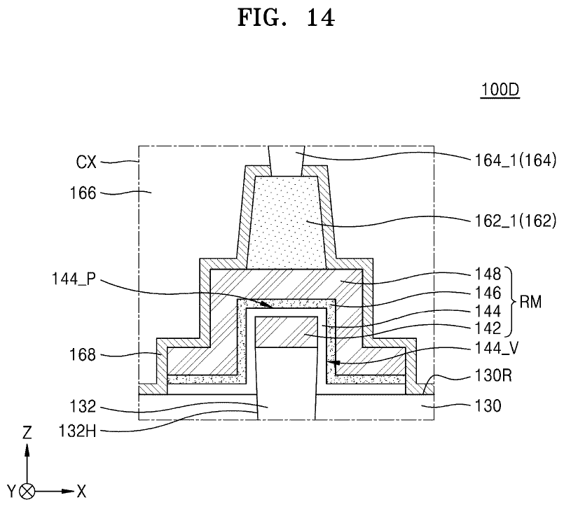

FIG. 13 is a cross-sectional view illustrating a resistive memory device 100D according to embodiments of the present inventive concept. FIG. 14 is an enlarged view of a region CX of FIG. 13.

Referring to FIGS. 13 and 14, a first interlayer insulation layer 130 may include a recess portion 130R, and a sidewall of a lower electrode 142 may be aligned with the recess portion 130R. For example, the sidewall of the lower electrode 142 may be substantially aligned with a sidewall of the recess portion 130R. The recess portion 130R may be disposed at a vertical level which is lower than an upper surface of a contact 132, and the contact 132 may protrude upward with respect to the recess portion 130R.

A variable resistive material pattern 144 may be conformally disposed on an upper surface and a sidewall of the lower electrode 142, and an end portion of the variable resistive material pattern 144 may extend to the recess portion 130R of the first interlayer insulation layer 130 or a sidewall of the contact 132. For example, the variable resistive material pattern 144 may extend along the sidewall of the contact 132 to extend along the recess portion 130R. A portion of the variable resistive material pattern 144 disposed on an upper surface of the lower electrode 142 may be referred to as a horizontal extension portion 144_P, and a portion of the variable resistive material pattern 144 which is disposed on a sidewall of the lower electrode 142 and extends to the sidewall of the contact 132 may be referred to as a vertical extension portion 144_V. A portion of each of a middle conductive pattern 146 and an upper electrode 148, each of which are disposed on the vertical extension portion 144_V, may extend into the recess portion 130R and/or onto the sidewall of the contact 132.

As an electric field concentrates in a boundary region between the horizontal extension portion 144_P and the vertical extension portion 144_V of the variable resistive material pattern 144, the difference between a resistance value of a low resistance state and a resistance value of a high resistance state may be maximized, and thus, the device performance of the resistive memory device 100D may be increased.

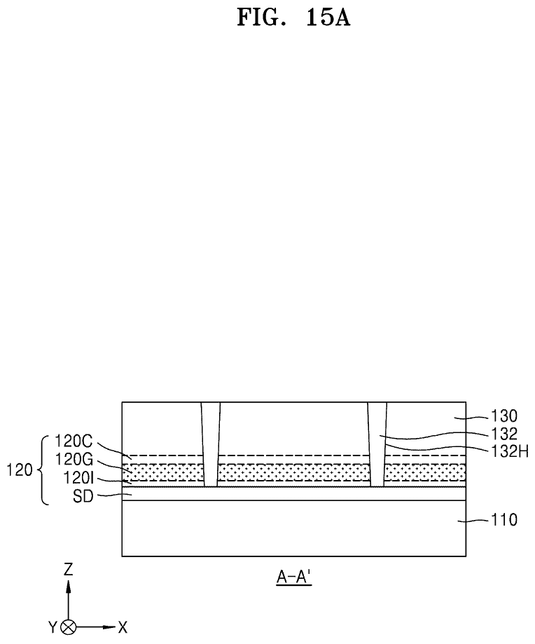

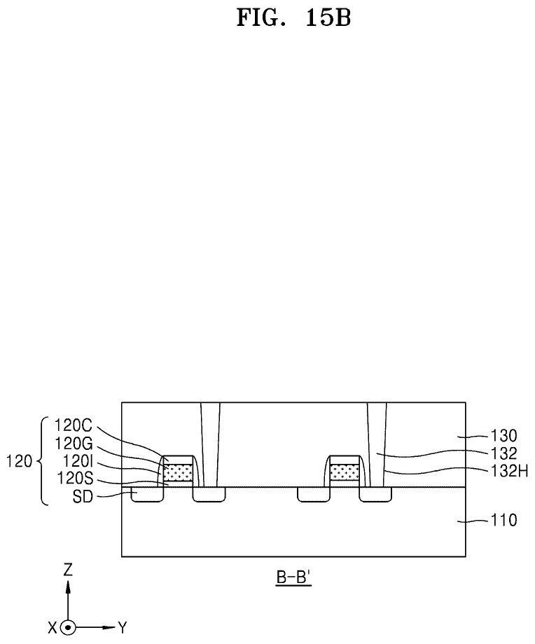

FIGS. 15A, 15B, 16A, 16B, 17A, 17B, 18A, 18B, 19A, 19B, 20A, 20B, 21A, 21B, 22A, 22B, 23A, 23B, 24A, and 24B are cross-sectional views illustrating a method of manufacturing a resistive memory device 100, according to embodiments of the present inventive concept.

Referring to FIGS. 15A and 15B, a transistor 120 may be formed on a substrate 110. First, a gate insulation layer 120I, a gate electrode 120G, and a gate capping layer 120C sequentially disposed on an upper surface of the substrate 110 may be formed, and then, a gate spacer 120S may be formed on a sidewall of each of the gate insulation layer 120I, the gate electrode 120G, and the gate capping layer 120C. A source/drain region SD may be formed by implanting an impurity ion into the substrate 110, at both sides of the gate spacer 120S.

Subsequently, a first interlayer insulation layer 130 covering the transistor 120 may be disposed on the substrate 110. A contact hole 132H exposing a portion (for example, a portion of a source/drain region SD) of a transistor 120 may be formed by removing a portion of the first interlayer insulation layer 130, and a conductive material may be formed in the contact hole 132H to form the contact 132.

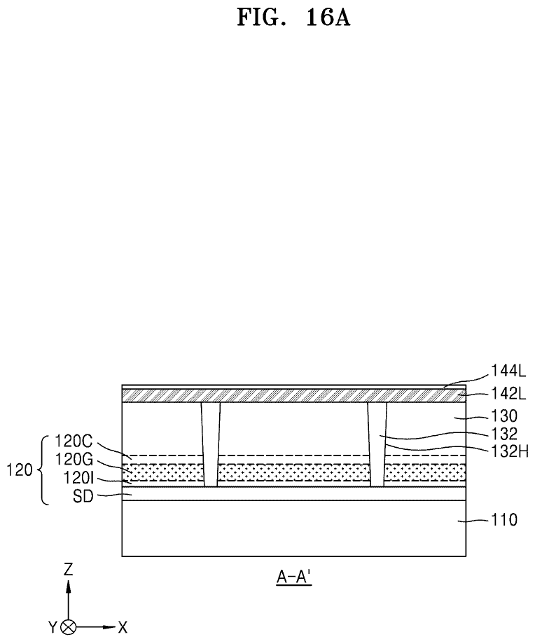

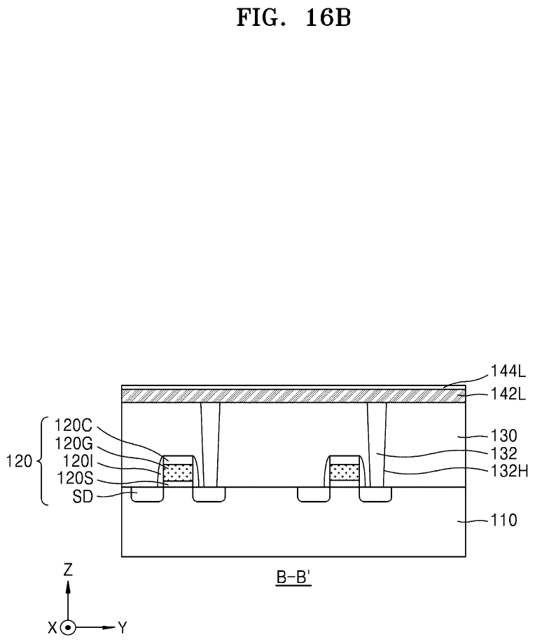

Referring to FIGS. 16A and 16B, a lower electrode layer 142L and a variable resistive material layer 144L may be sequentially formed on the first interlayer insulation layer 130.

In embodiments of the present inventive concept, the lower electrode layer 142L may include at least one of titanium, titanium nitride, aluminum, platinum, tantalum, and/or tantalum nitride. The variable resistive material layer 144L may include a perovskite-based material or transition metal oxide. The lower electrode layer 142L and the variable resistive material layer 144L may be formed by using a chemical vapor deposition (CVD) process or an atomic layer deposition process.

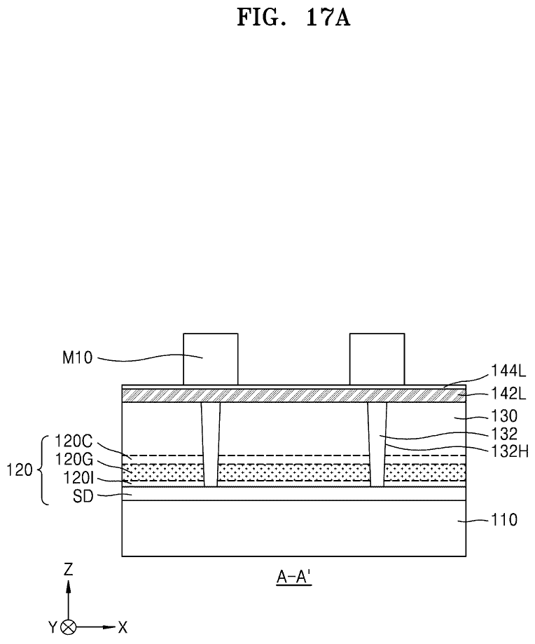

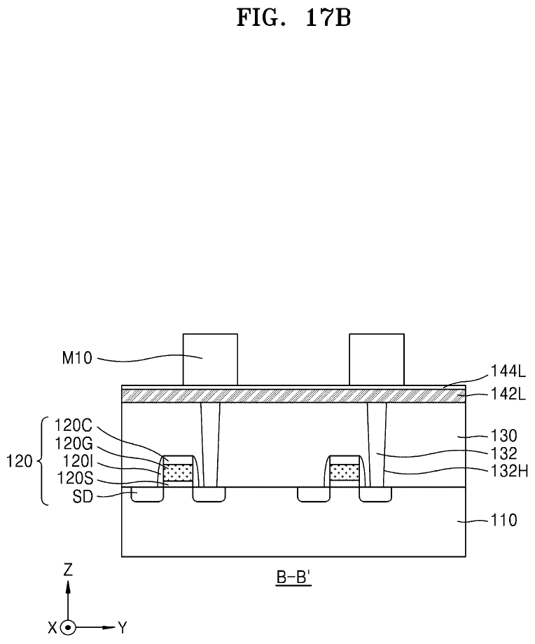

Referring to FIGS. 17A and 17B, a first mask pattern M10 may be formed on the variable resistive material layer 144L. The first mask pattern M10 may be a photoresist pattern.

In embodiments of the present inventive concept, the first mask pattern M10 may have a plurality of island portions which are arranged spaced apart from one another in a first horizontal direction X and a second horizontal direction Y.

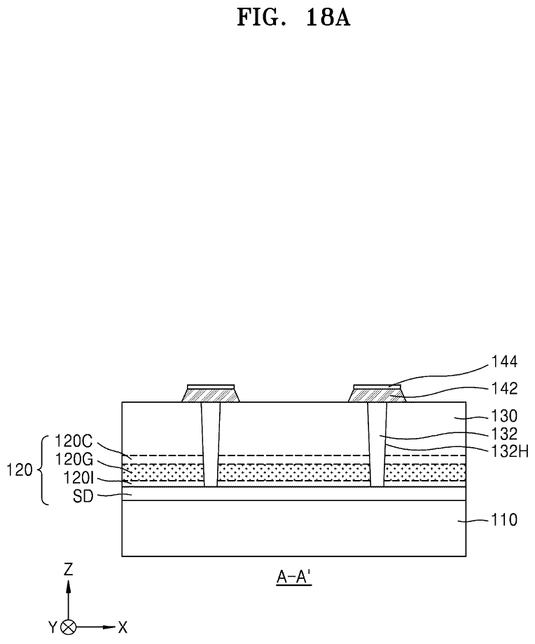

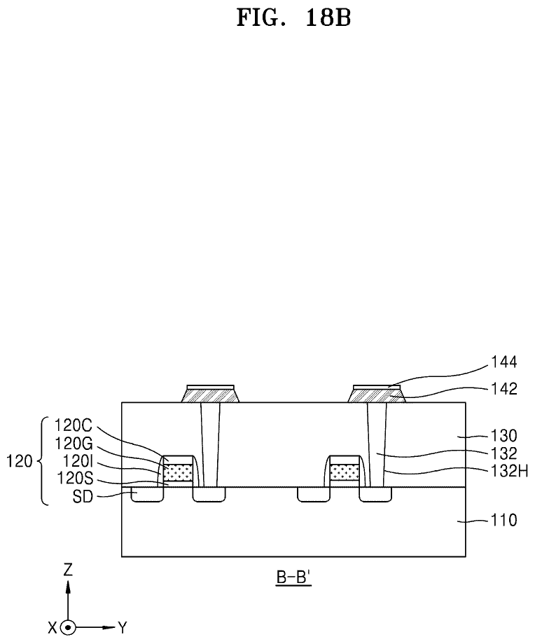

Referring to FIGS. 18A and 18B, a variable resistive material pattern 144 and a lower electrode 142 may be formed by sequentially patterning the variable resistive material layer 144L and the lower electrode layer 142L by using the first mask pattern M10 as an etch mask.

In embodiments of the present inventive concept, a patterning process of the variable resistive material layer 144L and the lower electrode layer 142L may be a wet etching process or a dry etching process.

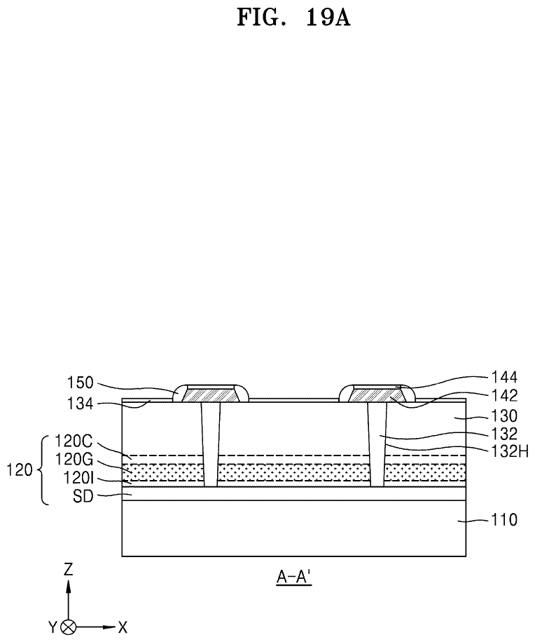

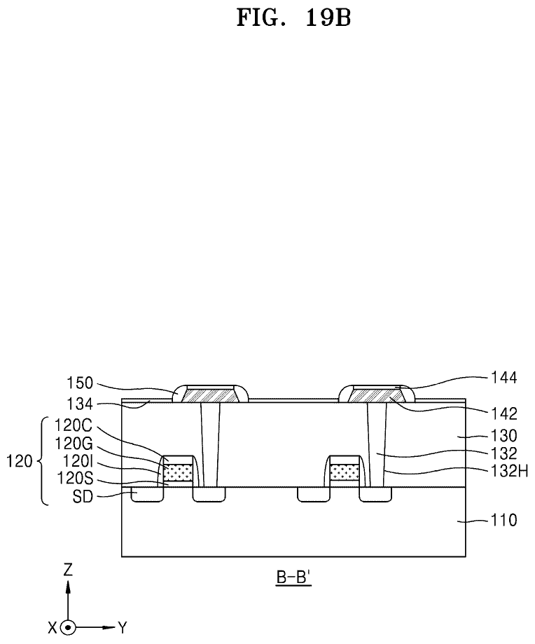

Referring to FIGS. 19A and 19B, an insulation layer covering the variable resistive material pattern 144 and the lower electrode 142 may be formed on an upper surface of the first interlayer insulation layer 130, and a spacer 150 may be formed in the insulation layer by an anisotropic etching process.

In embodiments of the present inventive concept, the spacer 150 may be formed to cover a sidewall of each of the variable resistive material pattern 144 and the lower electrode 142. For example, the spacer 150 may cover an entire sidewall of each of the variable resistive material pattern 144 and the lower electrode 142.

In embodiments of the present inventive concept, the etch stop layer 134 may be formed on the upper surface of the first interlayer insulation layer 130 before a process of forming the spacer 150 or after the process of forming the spacer 150. In embodiments of the present inventive concept, the etch stop layer 134 may be formed during a process of forming the spacer 150.

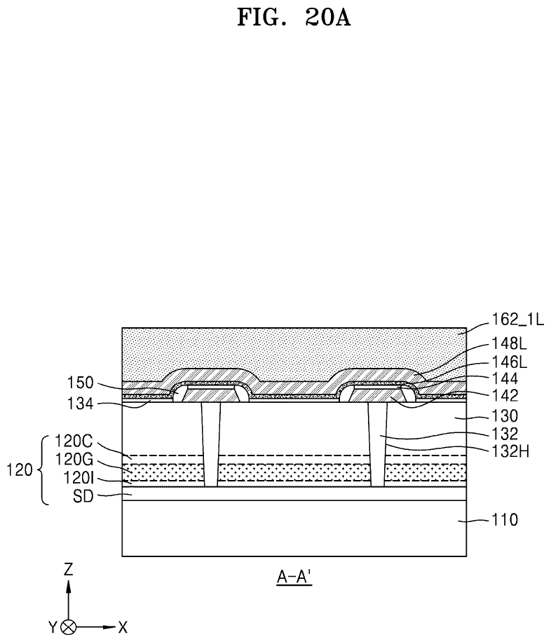

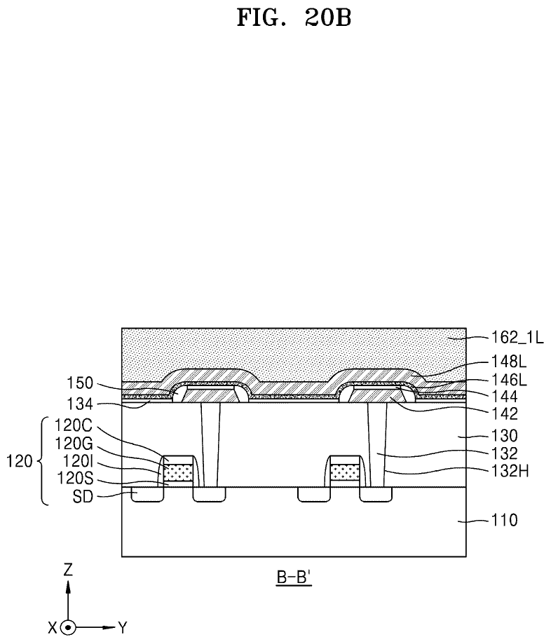

Referring to FIGS. 20A and 20B, a middle conductive layer 146L and an upper electrode layer 148L may be sequentially formed on the variable resistive material pattern 144, the spacer 150, and the upper surface of the first interlayer insulation layer 130 (or the upper surface of the etch stop layer 134). Subsequently, a first wiring layer 162_1L may be formed on the upper electrode layer 148L.

In embodiments of the present inventive concept, the middle conductive layer 146L may be formed by using titanium or titanium nitride. For example, the upper electrode layer 148L may be formed by using at least one of titanium, titanium nitride, aluminum, platinum, tantalum, and/or tantalum nitride. For example, the first wiring layer 162_1L may be formed by using aluminum or an aluminum alloy.

Referring to FIGS. 21A and 21B, a second mask pattern M20 may be formed on the first wiring layer 162_1L. The second mask pattern M20 may be a photoresist pattern.

In embodiments of the present inventive concept, the second mask pattern M20 may have a plurality of line shapes which extend in the second horizontal direction Y.

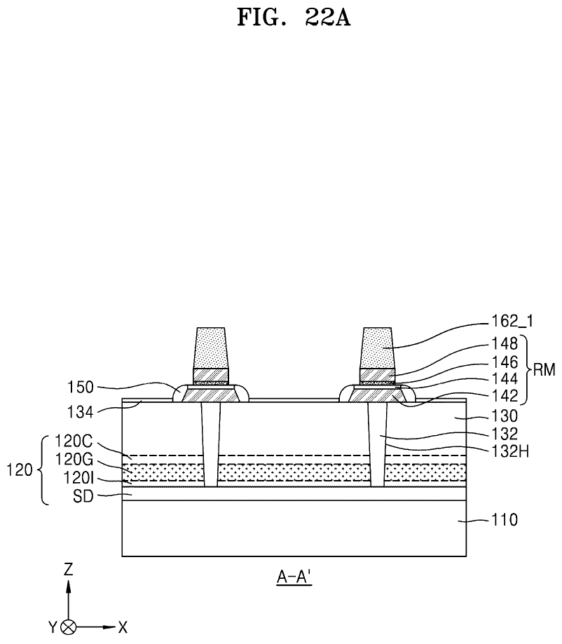

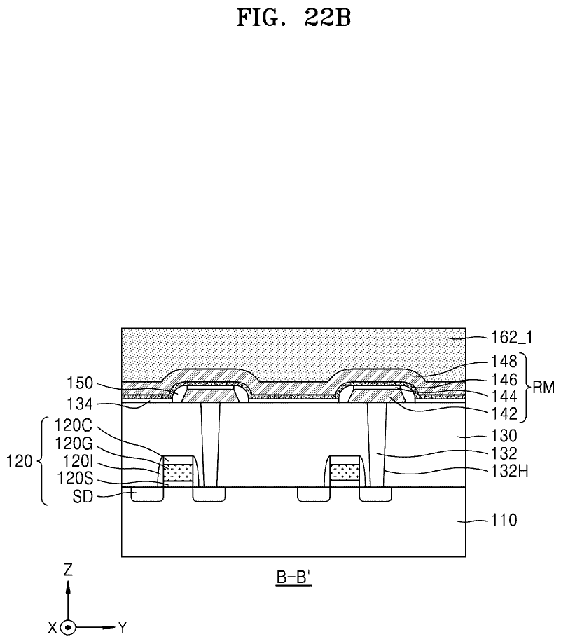

Referring to FIGS. 22A and 22B, a first wiring line 162_1, an upper electrode 148, and a middle conductive pattern 146 may be formed by sequentially patterning the first wiring layer 162_1L, the upper electrode layer 148L, and the middle conductive layer 146L by using the second mask pattern M20 as an etch mask.

In embodiments of the present inventive concept, the first wiring line 162_1, the upper electrode 148, and the middle conductive pattern 146 may have a plurality of line shapes which extend in the second horizontal direction Y.

In embodiments of the present inventive concept, by sequentially patterning the first wiring layer 162_1L, the upper electrode layer 148L, and the middle conductive layer 146L by using the second mask pattern M20 as an etch mask, a lower surface of the first wiring line 162_1 may have a width that is the same or substantially the same as each of a width of an upper surface of the upper electrode 148 disposed under the first wiring line 162_1 and a width of an upper surface of the middle conductive pattern 146 disposed under the upper electrode 148. For example, an edge portion of the first wiring line 162_1 may be aligned or substantially aligned with a sidewall of the upper electrode 148 and a sidewall of the middle conductive pattern 146. For example, the sidewall of the first wiring line 162_1 and the sidewall of the upper electrode 148 may be connected to each other without a discontinuous portion between the sidewall of the first wiring line 162_1 and the sidewall of the upper electrode 148.

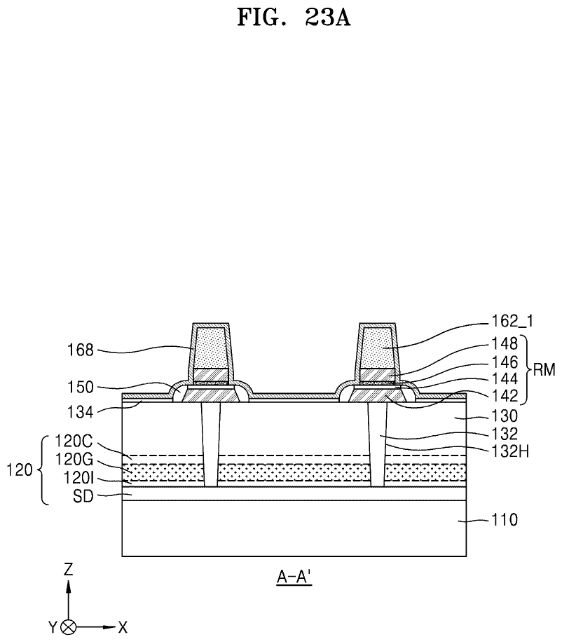

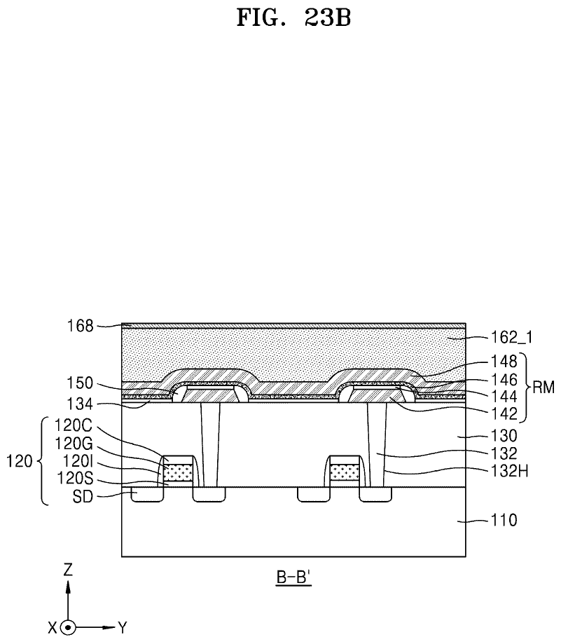

Referring to FIGS. 23A and 23B, a capping liner 168 may be formed on an upper surface and a sidewall of the first wiring line 162_1. The capping liner 168 may extend from the upper surface and the sidewall of the first wiring line 162_1 onto the sidewall of the upper electrode 148 and the sidewall of the middle conductive pattern 146 and may be disposed on an upper surface of at least a portion of the variable resistive material pattern 144 which is not covered by the upper electrode 148.

In embodiments of the present inventive concept, the capping liner 168 may be formed by using silicon nitride or silicon oxide.

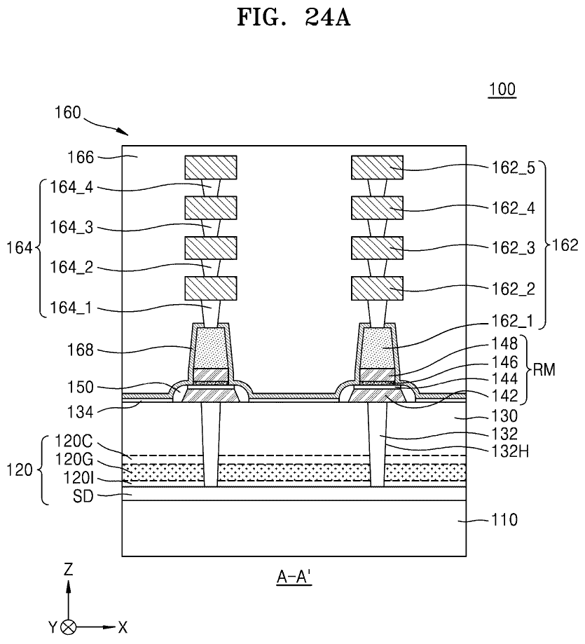

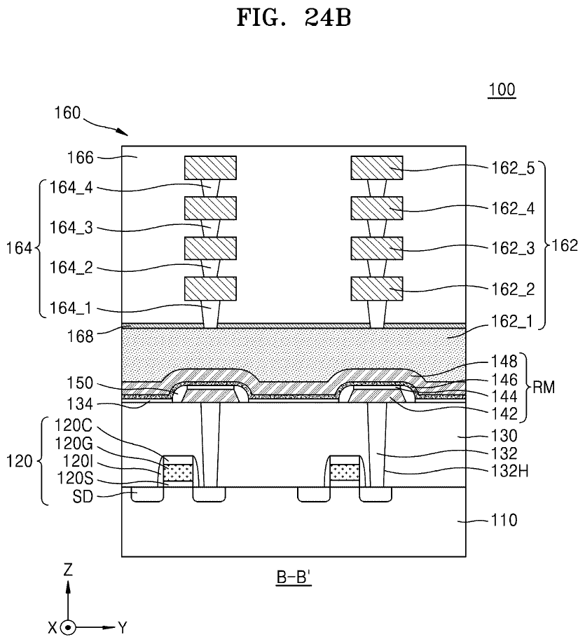

Referring to FIGS. 24A and 24B, a BEOL structure 160 may be formed by forming a plurality of vias 164, a plurality of wiring lines 162, and a second interlayer insulation layer 166 on the first wiring line 162_1.

The resistive memory device 100 may be formed by performing a process described above.

Generally, a memory cell including a variable resistive memory layer may be formed in a BEOL structure, and for example, may be disposed between an Mx wiring line (for example, a wiring line disposed at an x^{th} vertical level) and an Mx+1 wiring line (for example, a wiring line disposed at an x^{th}+1 vertical level). However, a difficulty level of a process of sequentially patterning an upper electrode, the variable resistive memory layer, and a lower electrode may be relatively high. During an etching process of the variable resistive memory layer, a process error where damage such as etch damage occurring on the upper electrode may occur, and due to this, the reliability of the memory cell may be reduced.

According to the embodiments described above, the upper electrode 148 and the middle conductive pattern 146 may be patterned together in a patterning process of the first wiring line 162_1. According to such a manufacturing method, etch damage may be minimized in a patterning process of the upper electrode 148. Accordingly, the resistive memory cell RM may have increased device performance or increased reliability, and the manufacturing cost of the resistive memory device 100 may be reduced.

The method of manufacturing the resistive memory device 100 illustrated in FIGS. 2 to 5 has been described above with reference to FIGS. 15A to 24B. The resistive memory devices 100A, 100B, and 100C according to embodiments of the present inventive concept may be manufactured by a modified method of the manufacturing method described above.

For example, to manufacture the resistive memory device 100A described above with reference to FIGS. 6 to 8, the lower electrode layer 142L, the variable resistive material layer 144L, the middle conductive layer 146L, and the upper electrode layer 148L may be sequentially formed on the first interlayer insulation layer 130. Subsequently, a first mask pattern may be formed on the upper electrode layer 148L, and then, the lower electrode 142, the variable resistive material pattern 144, the middle conductive pattern 146, and the upper electrode 148 may be formed by patterning the lower electrode layer 142L, the variable resistive material layer 144L, the middle conductive layer 146L, and the upper electrode layer 148L by using the first mask pattern as an etch mask. Subsequently, a spacer 150A may be formed on a sidewall of each of the lower electrode 142, the variable resistive material pattern 144, the middle conductive pattern 146, and the upper electrode 148, and then, a first wiring line 162_1 may be formed on the upper electrode 148.

For example, to manufacture the resistive memory device 100B described above with reference to FIGS. 9 and 10, the lower electrode layer 142L may be formed on the first interlayer insulation layer 130. Next, the first mask pattern may be formed on the lower electrode layer 142L, and then, the lower electrode 142 may be formed by patterning the lower electrode layer 142L by using the first mask pattern as an etch mask. Subsequently, the variable resistive material layer 144L, the middle conductive layer 146L, and the upper electrode layer 148L may be sequentially formed on the lower electrode 142, and a second mask pattern may be formed on the upper electrode layer 148L. Then, the variable resistive material pattern 144, the middle conductive pattern 146, and the upper electrode 148 may be formed by sequentially patterning the variable resistive material layer 144L, the middle conductive layer 146L, and the upper electrode layer 148L by using the second mask pattern as an etch mask. For example, the variable resistive material layer 144L may be patterned such that it is conformally formed on the upper surface and sidewalls of the lower electrode 142, and the middle conductive layer 146L and the upper electrode layer 148L may be patterned such that they are conformally formed on the variable resistive material layer 144L. Subsequently, a first wiring line 162_1 may be formed on the upper electrode 148.

For example, to manufacture the resistive memory device 100C described above with reference to FIGS. 11 and 12, the lower electrode layer 142L may be formed on the first interlayer insulation layer 130, and then, the first mask pattern may be formed on the lower electrode layer 142L. Subsequently, the lower electrode 142 may be formed by patterning the lower electrode layer 142L by using the first mask pattern as an etch mask. In a process of patterning the lower electrode 142, a recess portion 130R may be formed by removing a portion of the first interlayer insulation layer 130 together with the portions of the lower electrode layer 142L that are removed. Subsequently, the variable resistive material layer 144L, the middle conductive layer 146L, and the upper electrode layer 148L may be sequentially formed on the lower electrode 142, and then, a second mask pattern may be formed on the upper electrode layer 148L. Next, the variable resistive material pattern 144, the middle conductive pattern 146, and the upper electrode 148 may be formed by sequentially patterning the variable resistive material layer 144L, the middle conductive layer 146L, and the upper electrode layer 148L by using the second mask pattern as an etch mask. Subsequently, a first wiring line 162_1 may be formed on the upper electrode 148. Based on such a process, the variable resistive material pattern 144 including a horizontal extension portion 144_P and a vertical extension portion 144_V may be formed.

For example, to manufacture the resistive memory device 100D described above with reference to FIGS. 13 and 14, the lower electrode 142 may be formed on the first interlayer insulation layer 130, and the recess portion 130R may be formed in the first interlayer insulation layer 130 by performing a recess process of lowering an upper surface level of the first interlayer insulation layer 130. Subsequently, the variable resistive material layer 144L, the middle conductive layer 146L, and the upper electrode layer 148L may be sequentially formed on the lower electrode 142, and then, a mask pattern may be formed on the upper electrode layer 148L. Subsequently, the variable resistive material pattern 144, the middle conductive pattern 146, and the upper electrode 148 may be formed by sequentially patterning the variable resistive material layer 144L, the middle conductive layer 146L, and the upper electrode layer 148L by using the mask pattern as an etch mask. Subsequently, a first wiring line 162_1 may be formed on the upper electrode 148. Based on such a process, the variable resistive material pattern 144 including a horizontal extension portion 144_P and a vertical extension portion 144_V may be formed.

In a resistive memory device according to an embodiment of the present inventive concept, a variable resistive memory cell may be disposed under a first wiring line, which includes aluminum and is disposed at a lowermost portion of a plurality of wiring lines, of a BEOL structure, and an upper electrode of the variable resistive memory cell may be simultaneously patterned in a patterning process of the first wiring line. Accordingly, the manufacturing cost of a resistive memory device may be reduced, and a variable resistive memory cell may have increased device performance.

Hereinabove, embodiments have been described in the drawings and the specification. Embodiments have been described by using the terms described herein, but this has been merely used for describing the present inventive concept and has not been used for limiting a meaning or limiting the scope of the present inventive concept defined in the following claims. Therefore, it may be understood by those of ordinary skill in the art that various modifications and other equivalent embodiments may be implemented from the present inventive concept. Accordingly, the spirit and scope of the present inventive concept may be defined based on the spirit and scope of the following claims.

While the present inventive concept has been described with reference to embodiments thereof, it will be understood by those of ordinary skill in the art that various changes in form and details may be made thereto without departing from the spirit and scope of the present inventive concept.

What is claimed is:

1. A resistive memory device comprising:
a substrate;
a switching component disposed on the substrate;
a first interlayer insulation layer disposed on the substrate and covering the switching component;
a contact disposed in a contact hole, which passes through the first interlayer insulation layer, and electrically connected to the switching component;
a resistive memory unit disposed on the first interlayer insulation layer and electrically connected to the contact, wherein the resistive memory unit includes a lower electrode, a variable resistive material pattern, and an upper electrode sequentially disposed on the first interlayer insulation layer; and
a first wiring line disposed on the resistive memory unit and extending in a first horizontal direction that is parallel to an upper surface of the substrate, wherein the first wiring line includes aluminum.

2. The resistive memory device of claim 1, further comprising:
a second wiring line disposed at a vertical level which is higher than that of the first wiring line; and
a second interlayer insulation layer disposed on the first interlayer insulation layer and covering the first wiring line, the second wiring line, and the resistive memory unit.

3. The resistive memory device of claim 1, wherein a first portion of a lower surface of the lower electrode is disposed on an upper surface of the contact, and
a second portion of the lower surface of the lower electrode is disposed on an upper surface of the first interlayer insulation layer.

4. The resistive memory device of claim 1, wherein the lower electrode of the resistive memory unit extends in the first horizontal direction on the first interlayer insulation layer.

5. The resistive memory device of claim 1, wherein the variable resistive material pattern has a first width in a second horizontal direction intersecting with the first horizontal direction, and
the upper electrode has a second width which is less than the first width in the second horizontal direction.

6. The resistive memory device of claim 5, wherein an upper surface of the first wiring line has a third width in the second horizontal direction,
a lower surface of the first wiring line has a fourth width which is greater than the third width in the second horizontal direction, and
both sidewalls of the first wiring line are inclined so that a distance between the both sidewalls of the first wiring line increases as the lower surface of the first wiring line is approached from the upper surface of the first wiring line.

7. The resistive memory device of claim 1, further comprising a spacer at least partially surrounding a sidewall of the resistive memory unit,
wherein a portion of a lower surface of the first wiring line contacts the spacer.

8. The resistive memory device of claim 7, wherein a portion of the spacer is disposed between the first wiring line and the lower electrode, and the first wiring line is spaced apart from the lower electrode.

9. The resistive memory device of claim 1, wherein the switching component comprises a transistor.

10. The resistive memory device of claim 1, wherein the variable resistive material pattern comprises:
a horizontal extension portion disposed on an upper surface of the lower electrode; and
a vertical extension portion disposed on a sidewall of the lower electrode and connected to the horizontal extension portion.

11. The resistive memory device of claim 1, wherein the first interlayer insulation layer comprises a recess portion,
a first portion of the upper electrode extends into the recess portion, and
the variable resistive material pattern comprises:
a horizontal extension portion disposed outside of the recess portion; and
a vertical extension portion disposed on the lower electrode and disposed in the recess portion, wherein the vertical extension portion is connected to the horizontal extension portion.

12. A resistive memory device comprising:
a first interlayer insulation layer disposed on a substrate;
a resistive memory cell disposed on the first interlayer insulation layer; and
a back-end-of-line (BEOL) structure covering the resistive memory cell on the first interlayer insulation layer and including a plurality of wiring lines that are disposed at a plurality of vertical levels,
wherein the BEOL structure comprises a first wiring line that is disposed at a lowermost portion among the plurality of wiring lines, and
a lower surface of the first wiring line disposed on an upper surface of the resistive memory cell.

13. The resistive memory device of claim 12, wherein the resistive memory cell comprises:
a lower electrode disposed on the first interlayer insulation layer;
an upper electrode disposed on the lower electrode; and
a variable resistive material pattern disposed between the lower electrode and the upper electrode,
wherein the lower surface of the first wiring line is disposed directly on an upper surface of the upper electrode.

14. The resistive memory device of claim 13, further comprising a contact disposed in a contact hole that passes through the first interlayer insulation layer,
wherein a lower surface of the lower electrode is disposed on an upper surface of the contact.

15. The resistive memory device of claim 14, wherein the first wiring line extends in a first horizontal direction parallel to an upper surface of the substrate,
the variable resistive material pattern has a first width in a second horizontal direction intersecting with the first horizontal direction,
the upper electrode has a second width which is less than the first width in the second horizontal direction,
an upper surface of the first wiring line has a third width in the second horizontal direction,
a lower surface of the first wiring line has a fourth width which is greater than the third width in the second horizontal direction, and
both sidewalls of the first wiring line are inclined so that a distance between the both sidewalls of the first wiring line increases as the lower surface of the first wiring line is approached from the upper surface of the first wiring line.

16. The resistive memory device of claim 14, further comprising a spacer disposed on a sidewall of the resistive memory cell,
wherein a portion of the spacer is disposed between the first wiring line and the lower electrode, and the first wiring line is spaced apart from the lower electrode.

17. The resistive memory device of claim 14, further comprising a transistor disposed on the substrate,
wherein the contact is electrically connected to the transistor.

18. The resistive memory device of claim 13, wherein the variable resistive material pattern comprises:
a horizontal extension portion disposed on an upper surface of the lower electrode; and
a vertical extension portion disposed on a sidewall of the lower electrode and connected to the horizontal extension portion.

19. The resistive memory device of claim 13, wherein the first interlayer insulation layer comprises a recess portion,
a first portion of the upper electrode extends into the recess portion, and
the variable resistive material pattern comprises:
a horizontal extension portion disposed outside of the recess portion; and
a vertical extension portion disposed on the lower electrode and disposed in the recess portion, wherein the vertical extension portion is connected to the horizontal extension portion.

20. A resistive memory device comprising:
a substrate;
a transistor disposed on the substrate;
a first interlayer insulation layer disposed on the substrate and covering the transistor;
a contact disposed in a contact hole, which passes through the first interlayer insulation layer, and electrically connected to the transistor;
a resistive memory unit disposed on the first interlayer insulation layer and electrically connected to the contact;
a lower electrode disposed on the contact;
an upper electrode disposed on the lower electrode;
a variable resistive material pattern disposed between the lower electrode and the upper electrode;
a spacer disposed on a sidewall of the resistive memory unit;
a first wiring line disposed on the first interlayer insulation layer and extending in a first horizontal direction parallel to an upper surface of the substrate, wherein the first wiring line includes aluminum; and
a second interlayer insulation layer disposed on the first interlayer insulation layer and covering the resistive memory unit and the first wiring line.
